(19) United States
(12) Patent Application Publication
(10) Pub. No.: US 2016/0261954 A1
(43) Pub. Date: Sep. 8, 2016

(54) HIGH-FIDELITY SOUND REPRODUCTION EQUIPMENT

(71) Applicant: DEVIALET, Paris (FR)

(72) Inventors: Antoine PETROFF, Paris (FR); Pierre-Emmanuel CALMEL, Le Chesnay (FR); Jean-Loup AFRESNE, Paris (FR)

(73) Assignee: DEVIALET, Paris (FR)

(21) Appl. No.: 15/025,108

(22) PCT Filed: Sep. 26, 2014
(86) PCT No.: PCT/EP2014/070690

§ 371 Date: Mar. 25, 2016

(30) Foreign Application Priority Data
Sep. 26, 2013 (FR) 13 59302

(51) Int. Cl. H04R 3/08; H03G 5/16; H03F 3/181; H04R 29/00

(52) U.S. Cl. CPC H04R 3/08; H04R 29/001; H03G 5/165; H03F 3/181; H04R 2430/03

(57) ABSTRACT

A piece of sound reproduction equipment includes an input receiving an audio input signal to be reproduced; a loudspeaker with a resistance of less than 1Ω; a processing and amplification chain including: an amplifier able to energize the loudspeaker, a stage correcting the audio signal, positioned between the input and the amplifier, said correction stage is able to simulate virtual physical parameters of the loudspeaker by modifying the characteristics of the audio signal provided to the amplifier. The correction stage is able to modify the virtual physical parameters over time during operation of the sound reproduction system.

### CROSS-REFERENCE TO RELATED APPLICATIONS

This application is the U.S. National Phase of International Patent Application Serial No. PCT/EP2014/070690, filed Sep. 26, 2014, which claims priority to French Patent Application No. 1359302, filed Sep. 26, 2013, both of which are herein incorporated by reference in their entireties.

### FIELD OF THE INVENTION

The present invention relates to a piece of sound reproduction equipment, of the type including an input for receiving an audio input signal to be reproduced; a loudspeaker with a resistance of less than 1Ω; a processing and amplification chain including an amplifier capable of energizing the loudspeaker, and an audio signal correction stage, positioned between the input and the amplifier, which correction stage is able to simulate virtual physical parameters of the loudspeaker by modifying the characteristics of the audio signal provided to the amplifier.

### BACKGROUND

The piece of sound reproduction equipment generally includes an amplifier powering an electroacoustic system, which, in the majority of the cases, is a loudspeaker of the electrodynamic type (to be differentiated from loudspeakers of the electrostatic, piezoelectric, plasma, . . . type). In the following text, the term of loudspeaker relates to an electrodynamic type. The yield of such loudspeakers is very low, the latter being less than 5%. The losses are in majority due to heating of the wire forming the coil of the loudspeaker.

Loudspeakers currently used in equipment have a resistance from 4 to 8Ω.

The use of loudspeakers with lower resistances was contemplated in order to increase the yield of the equipment. It is observed that their yield is specially increased for acute sounds and little for bass sounds, while a high yield is mainly sought for bass sounds.

Further, the use of a loudspeaker with a low resistance typically less than 1Ω leads to a modification of the frequency response which is expressed by a degradation of the quality of the reproduced sound, requiring preliminary processing of the audio signal sent to the amplifier, in order to allow satisfactory listening to the reproduced sound.

Moreover, it is known how to virtually modify the parameters of a loudspeaker, notably by adding a virtual resistor to the coil of the loudspeaker or a virtual spring for modifying the flexibility, further called compliance, of the movable portion of the loudspeaker. This solution is notably known from document U.S. Pat. No. 4,118,600. This solution is not applied in document U.S. Pat. No. 4,118,600 for a loudspeaker of low resistance and only allows a global correction of a loudspeaker which is insufficient for allowing correction of the influence of the low resistor of the loudspeaker on the quality of the sound.

### SUMMARY

The object of the invention is to propose a sound reproduction equipment having loudspeaker with a high yield and producing a sound of quality.

For this purpose, the object of the invention is a piece of sound reproduction equipment of the aforementioned type, the correction stage being able to modify the virtual physical parameters overtime during the operation of the sound reproduction system.

According to particular embodiments, the piece of sound reproduction equipment includes one or several of the following features:
the processing and amplification chain includes means for adjusting at least one amplification parameter and the correction stage is able to modify the virtual physical parameters over time depending on the time-dependent change of the adjusted parameter for operation of the amplification;
the correction stage is able to modify the audio signal in order to simulate a lowering of the electric resistance of the loudspeaker as far as a virtual electric resistance of the loudspeaker, when the set value of the processing and amplification chain exceeds a predetermined threshold, along a predetermined curve;
the correction stage is able to modify the virtual physical parameters overtime depending on the characteristics of the audio input signal;
the correction stage is able to modify the audio signal in order to simulate a lowering of the resonance frequency of the loudspeaker as far as a virtual resonance frequency of the loudspeaker below the above frequencies of the audio signal to be reproduced;
the correction stage is able to modify the audio signal in order to simulate a displacement of the resonance frequency of the loudspeaker as far as a virtual resonance frequency of the loudspeaker according to a sweep of a predetermined range of frequencies according to a predetermined sweep rule;
the correction stage is able to modify the audio signal in order to simulate a displacement of the resonance frequency of the loudspeaker as far as a virtual resonance frequency of the loudspeaker depending on an analysis of the audio input signal;
the correction stage is able to simulate a modification of the compliance and/or of the mechanical resistance of the loudspeaker and/or of the mobile mass of the loudspeaker in order to modify the audio signal for simulating a displacement of the resonance frequency of the loudspeaker as far as a virtual resonance frequency of the loudspeaker;
the piece of sound reproduction equipment includes several correction stages able to modify the virtual physical parameters over time following modification rules different from each other and it includes means for agglomerating the audio signals modified by each correction stage in order to determine an agglomerated modified signal addressed to the amplifier.

### BRIEF DESCRIPTION OF THE DRAWINGS

The invention will be better understood upon reading the description which follows, only given as an example and made with reference to the drawings wherein:

FIG. 1 is a schematic view of a piece of sound reproduction equipment according to the invention;

FIG. 2 is a schematic view of the contents of a first processor of the piece of equipment of FIG. 1;

FIG. 3 is a flow chart explaining a mode for controlling the piece of equipment according to a first embodiment;

FIG. 4 is a graph illustrating the responses of a loudspeaker according to the invention and of a loudspeaker of the state of the art;

FIGS. 5, 6 and 7 are flow charts explaining modes for controlling the piece of equipment of the second, third and fourth embodiments; and

FIG. 8 is a schematic view of another embodiment of a piece of equipment according to the invention.

### DETAILED DESCRIPTION

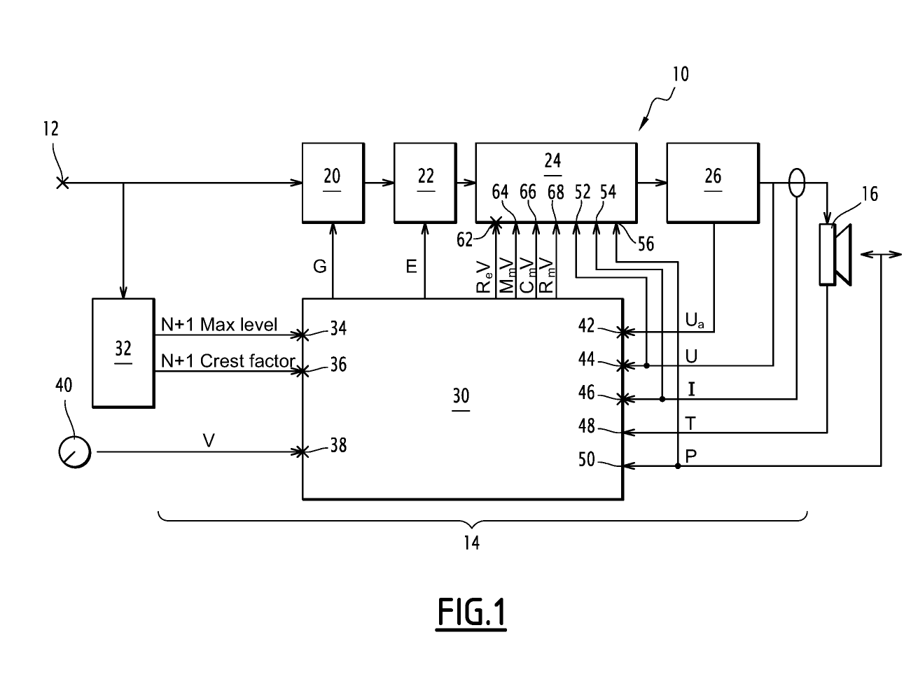

The piece of sound reproduction equipment 10 illustrated in FIG. 1 includes an input 12 for receiving an audio signal to be reproduced, a processing and amplification chain 14 for the signal and a loudspeaker 16.

The loudspeaker is a loudspeaker of the electrodynamic type including a magnet, a membrane held by a peripheral suspension and a coil for energizing the membrane suspended by a part commonly called a spider. The membrane is movable under the combined action of the magnet and of a variable electric current crossing the coil.

The loudspeaker is housed in the wall of an air volume, thereby forming a closed acoustic chamber, with a vent or a passive loudspeaker.

The loudspeaker is characterized by the following physical parameters corresponding to the actual physical characteristics of the loudspeaker without any electronic correction of the energizing signal:
I: length of the wire of the coil;
Rₑ: resistance of the coil;
Lₑ: inductance of the coil;
Mₘ: mobile mass of the loudspeaker;
Cₘ: flexibility or compliance (reciprocal of the stiffness of the diaphragm and of the gasket);
S_{d}: surface of the piston formed by the membrane and the peripheral portion of the gasket;
B: magnetic field of the magnet;
Rₘ: mechanical loss in the loudspeaker.

Advantageously, the loudspeaker is designed so that the coil has a resistance of less than 1Ω, the latter being preferably comprised between 50 mΩ and 500 mΩ and even more advantageously between 80 mΩ and 200 mΩ. To do this, the wire is selected to be of a large diameter and/or has a reduced length.

The processing and amplification chain 14 includes a pre-amplification stage 20 allowing the application of a global gain G to the audio input signal to be amplified. The pre-amplification stage 20 is connected at the input to the input 12.

The output of the pre-amplification stage 20 is connected to the input of an amplitude equalizer 22 depending on the frequency, able to ensure filtering according to a predetermined frequency response curve E forming a set value.

The output of the equalizer 22 is connected through a correction stage 24 giving the possibility of modifying the audio signal to be reproduced after pre-amplification and equalization in order to virtually simulate the modified physical parameters of the loudspeaker 16 positioned downstream.

Finally, the amplification and processing chain 14 includes a power amplifier 26, the input of which is connected at the output of the correction stage 24 and the output of which is connected to the loudspeaker 16. The amplifier 26 is a voltage source having a low output impedance, of less than 10 mΩ. Preferably, the amplifier 26 consists of an amplifier as described in patent application FR 2 873 872.

The processing and amplification chain 14 includes a main control unit 30 formed with a digital signal processor ensuring control of the pre-amplification 20, of equalization 22 and of correction 24 stages.

The main control unit 30 is connected to a unit 32 for preprocessing the input signal, which is directly connected to the input 12. The preprocessing unit 32 is able to continuously determine the maximum instantaneous amplitude level of the input acoustic signal from a multiband frequency analysis. This maximum instantaneous level noted as N+1 Max Level is provided on an input 34 of the main control unit 30.

Also, the preprocessing unit 32 is able to provide, on an input 36 of the main control unit 30, a pressed factor of the audio input signal resulting from a multiband frequency analysis. This pressed factor is noted as N+1 Crest Factor.

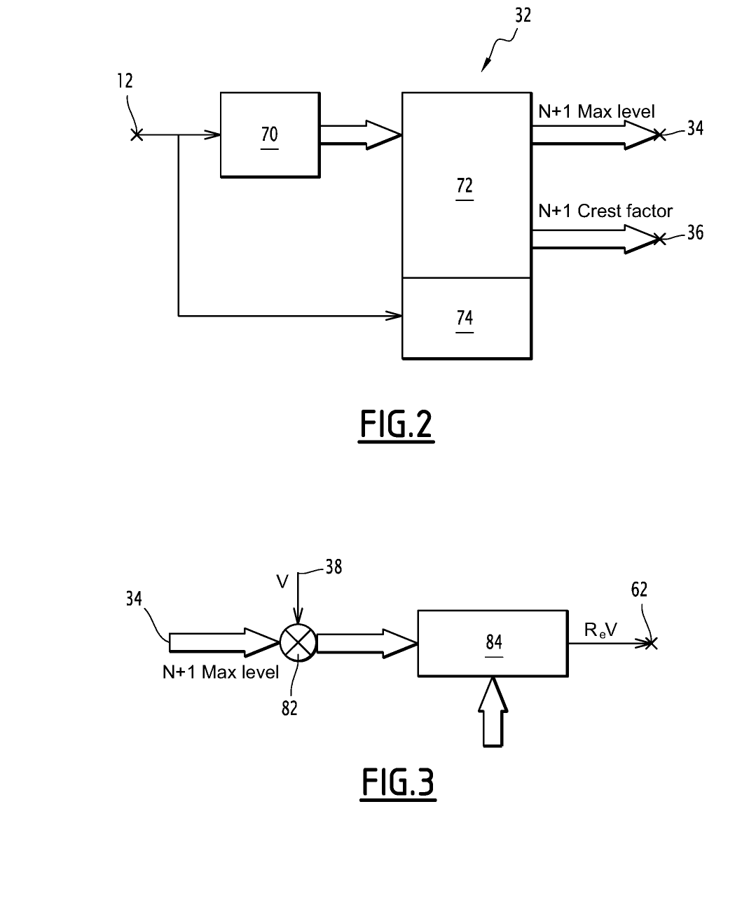

The detail of the preprocessing unit 32 will be described in detail with reference to FIG. 2.

On an input 38, the main control unit 30 is connected to a user interface 40, giving the possibility of setting a volume V set value representative of the sound level reckoned for the reproduced audio signal by the loudspeaker 16.

In order to ensure the control of the stages 20, 22 and 24, the main control unit 30 further receives on an input 42, a representative value of the voltage Uₐ for powering the amplifier 26. It also receives on the inputs 44 and 46 representative values, respectively of the voltage U and of the current I applied to the terminals of the loudspeaker 16. The values received on the inputs 42, 44 and 46 are directly measured on the amplifier 26 or at the output of the latter by any known suitable means.

Further, the main control unit 30 receives on inputs 48 and 50 representative values of the condition of the loudspeaker and notably of the operating temperature T on the input 48 and on the position P of the membrane of the loudspeaker on the input 50.

In order to allow application of the corrections required for modifying the virtual parameters of the loudspeaker, the correction stage 24 also receives on inputs 52, 54 and 56, representative values of the voltages U and current I applied to the loudspeaker, as well as of the current position P of the membrane of the loudspeaker.

The main control unit 30 is able, from one portion or from the totality of the representative values received on the inputs 34, 36, 38, 42, 44, 46, 48 and 50 to define control signals for the stages 20, 22 and 24.

In particular, it is able to calculate the global gain G applied at the input of the pre-amplification stage 20 as well as the frequency response equalization curve E applied to the equalization step 22.

The correction stage 24 is able to correct the resistance Rₑ of the loudspeaker in order to make it equal to a virtual value RₑV, the mobile mass Mₘ for making it equal to a virtual mobile mass MₘV, the compliance Cₘ for making it equal to a virtual compliance CₘV and the resistance Rₘ for making it equal to a virtual resistance RₘV of the suspension.

The processing operations carried out on the sound signal by the correction stage 24 are known per se for virtually modifying the physical parameters of the loudspeaker and will not be described in more detail. They are notably described in documents U.S. Pat. No. 4,118,600 and “Practical applications of a Closed Feedback Loop Transducer system equipped with Differential Pressure Control”, Audio Engineering Society, Convention Paper 8501, Presented at the 131st Convention, Oct. 20-23, 2011, New York, N.Y., USA.

The main control unit 30 is thus able to address on inputs 62, 64, 66 and 68 of the correction stage 24 set values respectively for la virtual series resistance RₑV, the virtual mobile mass MₘV, the virtual compliance CₘV and the virtual resistance of the suspension RₘV.

The preprocessing unit 32 is illustrated in detail in FIG. 2. In this figure, the input 12 for the audio signal to be reproduced and the inputs 34, 36 of the main control unit 30 are again found.

The preprocessing unit 32 is able to ensure an analysis of the input signal by separating the spectrum of the signal into several predefined frequency bands.

It includes a module 70 for computing a fast Fourier transform of the audio signal, the output of which is connected to a band analyzer 72. It further includes an analyzer 74 of a crest factor and for determining the maximum global level.

The analyzer 72 is able to provide, at the input 34, N+1 maximum intensity levels calculated for N predetermined frequencies of the signal and a maximum level for the whole of the signal. The analyzer 74 is able to provide from the audio signal, on input 36, N+1 pressed factors for the same analysis frequencies considered for the global signal.

The processing modes of the signals applied in the main control unit 30 will now be described.

The global gain G applied to the pre-amplification stage 20 is a function of the volume V set value received on the input 38 as known per se. It will not be described in more detail.

The equalization E set value applied to the equalizer 22 takes into account two components.

As known per se, it first ensures compensation for the psycho-acoustic attenuation. Depending of the volume V set value received on the input 38, the frequency response is adjusted for compensating losses in low frequencies below 120 Hz and the attenuation sensation of the high frequencies above 5 kHz at low listening volumes. The adjustment of the frequency response curve is achieved according to known equalization contour curves.

Further, the equalization set value E takes into account a frequency response compensation of the adjustment of the virtual parameters of the loudspeaker.

As known per se, certain adjustments of the virtual parameters of the loudspeaker change the frequency response of the global system. The equalization set value E is set for compensating these changes and for obtaining a flat final frequency response for the system in a predefined range of frequencies. The curve corresponding to the equalization set value is calculated according to the model of the virtual loudspeaker, by calculating the frequency response as an addition to the result obtained for the response of the loudspeaker with the selected virtual parameters.

The calculation flow chart for the set value of the virtual resistance RₑV applied on the input 62 is illustrated in FIG. 3.

From maximum levels N+1 Max Level received on the input 34 and from the volume V set value received on the input 38, the main control unit 30 determines the actual maximum level of the output signal of the amplifier 26 during a step 82 and then calculates, during a step 84, the set value of the virtual resistance RₑV to be applied depending on the actual acceptable maximum level of the loudspeaker, which depends on frequency.

The value of the virtual resistance RₑV is set for minimizing the low frequency response of the system according to the acceptable maximum power by the actual loudspeaker, this, in order to lower the virtual resistance for high sound levels so that the amplifier is able to provide the required voltage for energizing the loudspeaker. This control logic leads to decreasing the maximum voltage applied to the loudspeaker to the detriment of the relative level of the basses with respect to the remainder of the spectrum.

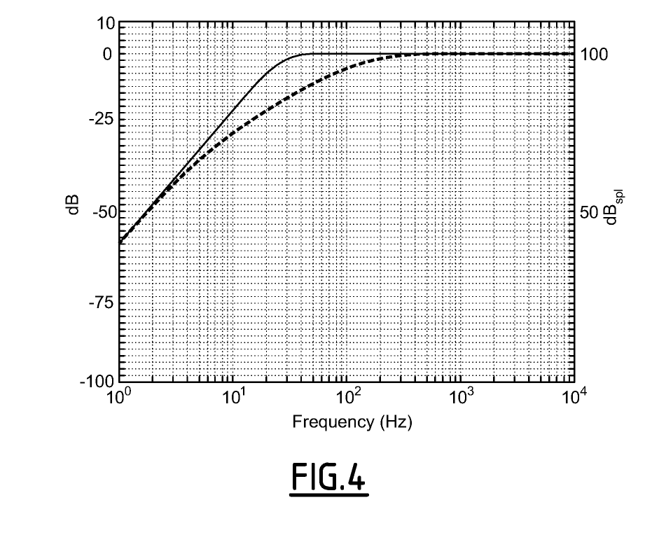

In FIG. 4 are illustrated in a solid line the response expressed in decibels versus frequency of a loudspeaker according to the invention and in dotted lines the response of a loudspeaker from the state of the art.

In practice, the resistance RₑV is lowered around the resonance frequency of the loudspeaker, when the set value of volume V exceeds a predetermined threshold.

In FIG. 5 is illustrated the flow chart for continuously calculating the parameters of the virtual loudspeaker relating to the virtual mobile mass MₘV, the virtual compliance CₘV and the resistance of the suspension RₘV.

From the input audio signal to be reproduced, a fast Fourier transform FFT, or more generally other frequency analysis overtime of the audio input signal, is calculated in step 90 by the block 70 of the preprocessing unit 32. In step 92, the lower frequencies are detected and a calculation is carried out in step 94 for determining the sought impedance of the virtual loudspeaker.

The determination of the sought impedance is made depending on the input signal so that the resonance frequency of the virtual loudspeaker is set below the lowest frequency contained in the input signal so that the impedance of the virtual loudspeaker is minimized on the whole of the spectrum which contains frequency components of the signal. La maximum voltage output of the voltage source formed by the amplifier 26 is thereby reduced.

The virtual mobile mass MₘV and virtual compliance CₘV parameters are calculated and set according to the following relationship defining the virtual resonance frequency of the loudspeaker from its characteristic parameters.

fᵣᵥ=fₛ\sqrt{1+α} [Hz] virtual resonance frequency

wherein

$${f}_{s} = \frac{1}{2 π \sqrt{MmV * CmV}} [ Hz ]$$

<<intermediate>> resonance frequency for the calculation

$$α = \frac{{V}_{as}}{{V}_{ab}}$$

$${V}_{as} = {CmVpc}^{2} {S}_{d}^{2} [ {m}^{3} ]$$

with c=sound velocity in air; p=specific gravity of air
and V_{ab}=Volume of air of the box
and Vₐₛ=Volume of air equivalent to the stiffness of the suspension of the loudspeaker
and MmV=Virtual mechanical mobile mass
and CmV=Virtual mechanical compliance

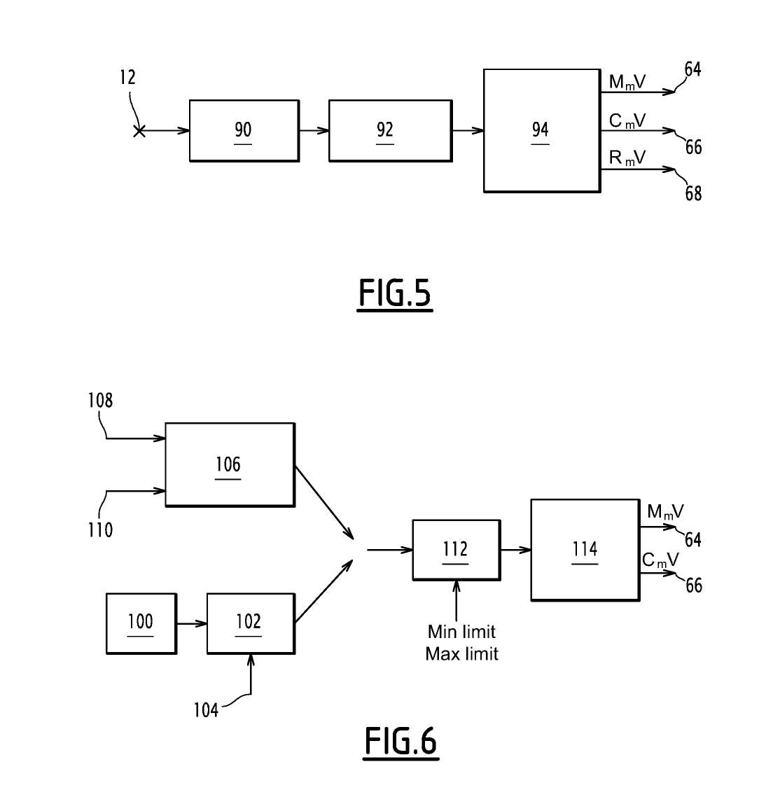

According to another embodiment, illustrated in FIG. 6, the parameters of the virtual loudspeaker are calculated continuously in order to ensure an arbitrary sweep of a predetermined frequency range by the virtual resonance frequency of the loudspeaker. The flow chart of these calculations is given in FIG. 6.

The virtual resonance frequency fluctuates between a lower limiting value min Limit and a maximum limiting frequency max Limit so that the impedance of the virtual loudspeaker is distributed and the maximum impedance is then limited.

For this purpose, a random signal is generated in step 100 by the main control unit 30. This random signal is used for controlling the sweep. This random signal is for example a random noise with a wide spectrum. The generator alternatively is a noise generator with a frequency shaping function for making the signal to noise ratio of the system maximum.

The signal from the random noise generator is filtered in step 102 depending on a predefined spectrum 104. This filter is an amplitude frequency response filter. The set value 104 is selected for maximizing the signal to noise ratio of the whole of the system.

A periodic wave is generated by a wave form generator in step 106 from a predetermined wave form type 108 and with a predetermined sweeping frequency 110. Between the maximum frequencies max Limit and minimal frequencies min Limit, a sweeping of the resonance frequency is determined in step 112 from the filtered random signal or from the filtered periodic wave.

The sweeping of the resonance frequency may either be ensured by a random signal (blocks 100, 102, 104) or by a periodic signal (blocks 106, 108, 110).

The random signal is of the wide spectrum noise type, and may be filtered for increasing the signal to noise ratio of the system.

The periodic signal is of the sine, triangular, square type, its frequency is adjusted for increasing the signal to noise ratio. The periodic signal may further be used for switching between M values corresponding to M virtual HPs according to a defined sequence.

In step 114, the main control unit 30 calculates the impedance of the virtual loudspeaker so that its resonance frequency corresponds to the frequency from step 112. For this purpose, step 114 determines the virtual mobile mass MₘV and the virtual compliance CₘV applied on the inputs 64 and 66, notably from the previous formula.

Thus for example, the virtual resonance frequency fluctuates from 20 Hertz to 100 Hertz by modifying the virtual parameters of the loudspeaker.

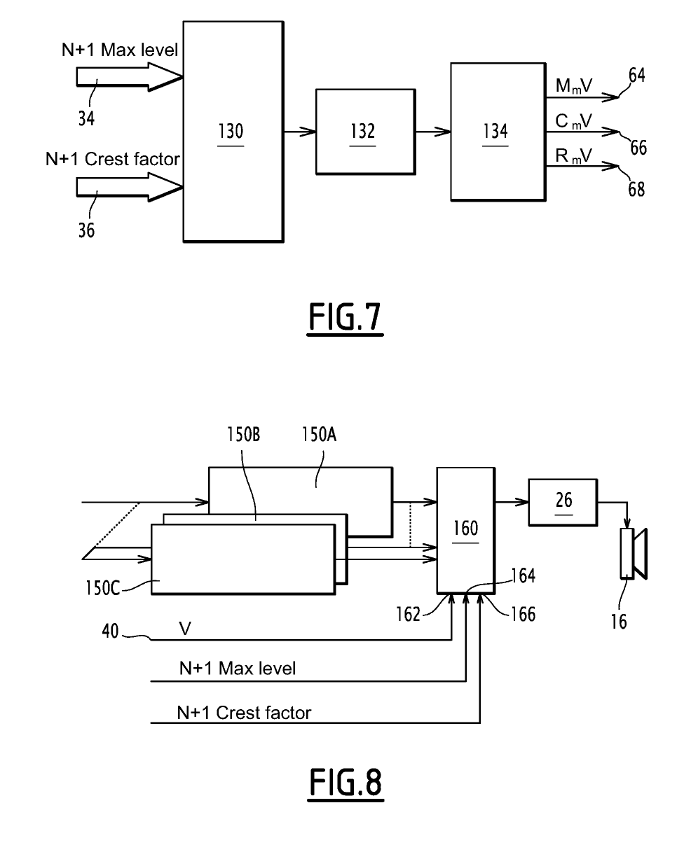

According to an alternative illustrated in FIG. 7, the continuous variation of the resonance frequency of the virtual loudspeaker is accomplished according to the frequencies of the audio signal to be reproduced.

For this purpose, the main control unit 30 considers the maximum intensity levels received on the input 34 and the crest factors received on the input 36. During a step for impedance optimization 130, an optimum impedance is calculated.

The optimum impedance of the virtual loudspeaker is established according to the analysis of the input signal so that the amplitude of the voltage which has to be provided by the power amplifier is maintained below a certain value, while allowing a high listening sound level.

The impedance is modified with the combined taking into account of the sweep of the resonance frequency and of the virtual resistance variation. These variations are continuous in amplitude or are discrete on M pre-selected values which correspond to M virtual loudspeakers according to two distinct embodiments.

The virtual resonance is calculated continuously so that the curve of the average overtime of the impedance is the envelope of the modulus of the Fast Fourier Transform (FTT) of the input signal.

According to a particular embodiment of the invention, the main control unit 30, and the correction stage 24 are replaced with several correction modules each including a main control unit and a correction stage, illustrated in FIG. 8 by references 150A, 150B, 150C. Each module is programmed so as to ensure correction of the audio signal depending on a different virtual loudspeaker. The audio signal to be reproduced after pre-amplification and equalization is introduced into each correction module 150A, 150B, 150C.

The outputs of the correction modules are connected to an average and summing stage 160 able to ensure a combination of the processed signals in the correction modules 150A, 150B, 150C.

The output signal of stage 160 is addressed to the amplification stage 26, which as previously energizes the loudspeaker 16.

The signals from the modules 150A, 150B, 150C are added and averaged, while taking into account the set value level of the volume V from the interface 40, and of the maximum intensity levels and of the crest factors from the preprocessing unit 32.

The combination of the following processed audio signals of the different virtual loudspeakers gives the possibility of obtaining a reproduced sound signal of high quality since it gives the possibility of compensating for the effects due to the particular shape of the closed volume in which the loudspeaker is mounted.

1. A piece of sound reproduction equipment including:
an input receiving an audio input signal to be reproduced;
a loudspeaker with a resistance of at least;
a processing and amplification chain comprising:
an amplifier able to energize the loudspeaker,
a stage correcting of the audio signal, positioned between the input and the amplifier, which correction stage is able to simulate virtual physical parameters of the loudspeaker by modifying the characteristics of the audio signal provided to the amplifier
wherein the correction stage is able to modify the virtual physical parameters over time during operation of the sound reproduction system.

2. The piece of sound reproduction equipment according to claim 1, wherein the processing and amplification chain comprises an adjustor adjusting at least one amplification parameter and in that the correction stage is able to modify the virtual physical parameters over time depending on the time-dependent change of the adjusted parameter for operation of the amplification.

3. The piece of sound reproduction equipment according to claim 2, wherein the correction stage is able to modify the audio signal in order to simulate a lowering of the electric resistance of the loudspeaker down to a virtual electric resistance of the loudspeaker, when the set volume value of the processing and amplification chain exceeds a predetermined threshold, according to a predetermined curve.

4. The piece of sound reproduction equipment according to claim 1, wherein the correction stage is able to modify the virtual physical parameters over time depending on the characteristics of the audio input signal.

5. The piece of sound reproduction equipment according to claim 4, wherein the correction stage is able to modify the audio signal in order to simulate lowering of the resonance frequency of the loudspeaker as far as a virtual resonance frequency of the loudspeaker below the frequencies of the audio signal to be reproduced.

6. The piece of sound reproduction equipment according to claim 1, wherein the correction stage is able to modify the audio signal for simulating displacement of the resonance frequency of the loudspeaker as far as a virtual resonance frequency of the loudspeaker following a sweep of a range of predetermined frequencies according to a predetermined sweeping rule.

7. The piece of sound reproduction equipment according to claim 1, wherein the correction stage is able to modify the audio signal in order to simulate a displacement of the resonance frequency of the loudspeaker as far as a virtual resonance frequency of the loudspeaker depending on an analysis of the audio input signal

8. The piece of sound reproduction equipment according to claim 5, wherein the correction stage is able to simulate a modification of the compliance of at least one of the mechanical resistance of the loudspeaker and the mobile mass of the loudspeaker in order to modify the audio signal for simulating a displacement of the resonance frequency of the loudspeaker as far as a virtual resonance frequency of the loudspeaker.

9. The piece of sound reproduction equipment according to claim 1, further comprising:
several correction stages able to modify the virtual physical parameters over time according to modification rules different from each other; and
an agglomerator agglomerating audio signals modified by each correction stage in order to determine an agglomerated modified signal addressed to the amplifier.
